(19) United States
(12) Patent Application Publication
(10) Pub. No.: US 2026/0051465 A1
(43) Pub. Date: Feb. 19, 2026

(54) SEMICONDUCTOR WAFER PROCESSING APPARATUS

(71) Applicant: SAMSUNG ELECTRONICS CO., LTD., Suwon-si (KR)

(72) Inventors: Junho IM, Suwon-si (KR); Jisoo IM, Suwon-si (KR); Manick Ha, Suwon-si (KR); Hakyoung KIM, Suwon-si (KR); Dougyong SUNG, Suwon-si (KR)

(73) Assignee: SAMSUNG ELECTRONICS CO., LTD., Suwon-si (KR)

(21) Appl. No.: 19/016,796

(22) Filed: Jan. 10, 2025

(30) Foreign Application Priority Data
Aug. 14, 2024 (KR) 10-2024-0108888

(51) Int. Cl. H01J 37/32; H01L 21/683

(52) U.S. Cl. CPC H01J 37/32697; H01J 37/3211; H01J 37/32715; H01L 21/6831; H01J 2237/334

(57) ABSTRACT

A semiconductor wafer processing apparatus includes a plasma chamber, a processing chamber connected to the plasma chamber and including an electrostatic chuck configured to support a semiconductor wafer, a plurality of grid electrodes between the plasma chamber and the processing chamber, and through-holes extending through the plurality of grid electrodes, where the plurality of grid electrodes include a first grid electrode and a second grid electrode spaced apart from the first grid electrode in a direction from the plasma chamber to the processing chamber and at least one of the first grid electrode and the second grid electrode includes a plurality of electrode plates.

### CROSS-REFERENCE TO RELATED APPLICATION

This application is based on and claims priority to Korean Patent Application No. 10-2024-0108888, filed on Aug. 14, 2024 in the Korean Intellectual Property Office, the disclosure of which is incorporated by reference herein in its entirety.

### BACKGROUND

Example embodiments of the disclosure relate to a semiconductor wafer processing apparatus.

Among semiconductor processes for manufacturing semiconductor devices, semiconductor wafer processing equipment using plasma processes may perform etching, physical vapor deposition (PVD), chemical vapor deposition (CVD), and resist removal deposition processes.

Recently, as semiconductor substrates have become more highly integrated and miniaturized, design rules are being reduced, and high-difficulty processes such as extreme ultraviolet (EUV) processes are being applied. As a result, technologies that may improve semiconductor process performance in semiconductor wafer processing equipment are being demanded.

In semiconductor processes using plasma, issues exist with plasma-induced damage (PID) and wafer charging by ions.

For example, in semiconductor wafer processing equipment, ion beam equipment may enable etching of the required target through low-energy ion beams with directionality, but ion beam equipment may cause PID or wafer charging caused by ions.

In addition, ion beam equipment may also have issues with plasma distribution on semiconductor wafers. To prevent such problems, the ion beam equipment may generate uniform plasma by rotating an electrostatic chuck or using an inductively coupled plasma (ICP) antenna.

However, this dispersion improvement method is not precise in control and has limitations in improving the dispersion between a center and an edge of the wafer.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor wafer processing apparatus in which a plasma distribution of a wafer may be precisely improved.

One or more example embodiments further provide a semiconductor wafer processing apparatus including a neutral beam facility for neutralizing ions that may be capable of alleviating a charging problem.

One or more example embodiments further provide a semiconductor wafer processing apparatus in which both plasma distribution improvement and charging problems may be simultaneously resolved.

Additional aspects will be set forth in part in the description which follows and, in part, will be apparent from the description, or may be learned by practice of the presented embodiments.

According to an aspect of an example embodiment, a semiconductor wafer processing apparatus may include a plasma chamber, a processing chamber connected to the plasma chamber and including an electrostatic chuck configured to support a semiconductor wafer, a plurality of grid electrodes between the plasma chamber and the processing chamber, and through-holes extending through the plurality of grid electrodes, where the plurality of grid electrodes include a first grid electrode and a second grid electrode spaced apart from the first grid electrode in a direction from the plasma chamber to the processing chamber and at least one of the first grid electrode and the second grid electrode includes a plurality of electrode plates.

According to an aspect of an example embodiment, a semiconductor wafer processing apparatus may include a plasma chamber in which ions are generated, a processing chamber configured to process a semiconductor wafer using ions generated in the plasma chamber, an ion extraction device configured to extract and accelerate ions in the plasma chamber and including a plurality of grid electrodes, and through-holes extending through the plurality of grid electrodes, where the plurality of grid electrodes include a first grid electrode and a second grid electrode spaced apart from the first grid electrode in a direction from the plasma chamber to the processing chamber, at least one of the first grid electrode and the second grid electrode includes a plurality of electrode plates, and voltages having different potential differences are applied to the plurality of electrode plates, respectively.

According to an aspect of an example embodiment, a semiconductor wafer processing apparatus may include a plasma chamber, an inductively coupled plasma antenna on an upper side of the plasma chamber, a processing chamber connected to and communicating with the plasma chamber, the processing chamber including an electrostatic chuck configured to support a semiconductor wafer, an ion extraction device between the plasma chamber and the processing chamber, the ion extraction device including an insulator and a plurality of grid electrodes, through-holes extending through the plurality of grid electrodes, and a reflector between the ion extraction device and the semiconductor wafer, and configured to neutralize an ion beam extracted from the ion extraction device, the reflector including a plurality of reflector plates that are continuously inclined with respect to the plurality of grid electrodes, where the plurality of grid electrodes include a first grid electrode, a second grid electrode and a third grid electrode sequentially arranged in a direction from the plasma chamber to the processing chamber, the insulator includes a first insulating plate between the first grid electrode and a second insulating plate between the second grid electrode and the third grid electrode, and at least one of the first grid electrode, the second grid electrode, and the third grid electrode includes a plurality of electrode plates, and voltages having different potential differences are respectively applied to the plurality of electrode plates.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view of a semiconductor wafer processing apparatus according to one or more embodiments;

FIG. 2 is a diagram of a semiconductor wafer processing apparatus according to one or more embodiments;

FIG. 3 is a perspective view of a plurality of grid electrodes according to one or more embodiments;

FIG. 4 is a plan view of a grid electrode according to one or more embodiments;

FIG. 5 is a cross-sectional view partially enlarged along line A-A′ of FIG. 4 according to one or more embodiments;

FIG. 6 is a cross-sectional perspective view illustrating a plurality of grid electrodes buried in an insulator according to one or more embodiments;

FIG. 7 is a cross-sectional view as viewed in the direction of arrow B of FIG. 6 according to one or more embodiments;

FIG. 8 is a diagram of a semiconductor wafer processing apparatus according to one or more embodiments;

FIG. 9 is a diagram of a semiconductor wafer processing apparatus according to one or more embodiments;

FIG. 10 is a diagram of an ion beam being neutralized into a neutral beam through a reflector used in a semiconductor wafer processing apparatus according to one or more embodiments;

FIG. 11A is a diagram illustrating simulation of the ion discharge shape when a first grid electrode and a second grid electrode are not divided into a center region and an edge region according to one or more embodiments;

FIG. 11B is a diagram illustrating simulation of the ion discharge shape when the first grid electrode and the second grid electrode are divided into a center region and an edge region according to one or more embodiments;

FIGS. 12A and 12B are graphs illustrating experimental results of etching rates according to one or more embodiments;

FIGS. 12C and 12D are graphs illustrating experimental results of etching rates according to one or more embodiments;

FIGS. 13A and 13B are graphs illustrating experimental results of an etching rate according to one or more embodiments;

FIGS. 13C and 13D are graphs illustrating experimental results of an etching rate according to one or more embodiments;

FIG. 14 is a diagram of an ion beam being neutralized by a reflector according to one or more embodiments; and

FIG. 15 is a diagram of an ion beam being neutralized by a reflector according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Expressions such as “first”, “second” and the like are used to distinguish one component from another component and do not limit the order and/or importance of the components. In some cases, the first component may be named the second component, and similarly, the second component may be named the first component without departing from the scope of rights. The terms of a singular form may include plural forms unless otherwise specified. In addition, when a certain part “includes” a certain component, it means that other components may be further included rather than excluding other components unless otherwise stated.

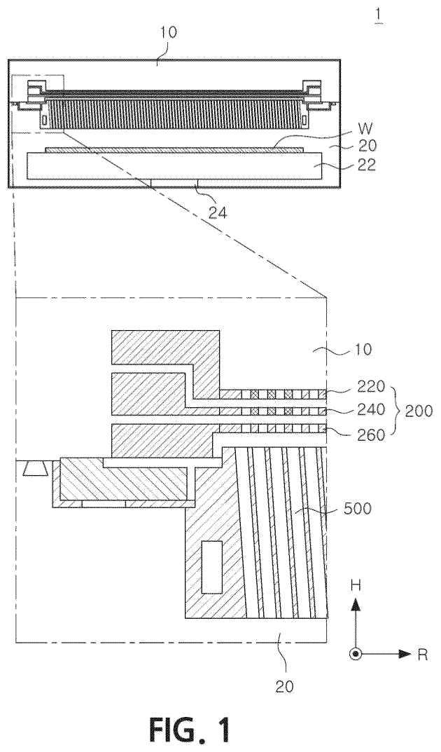

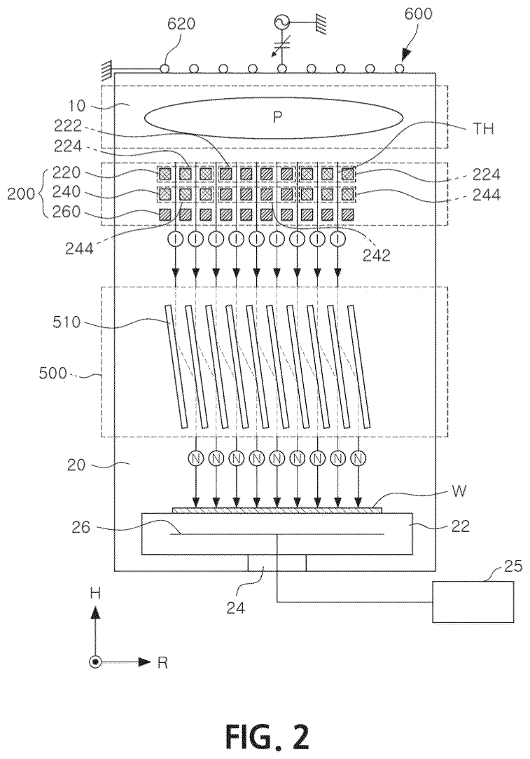

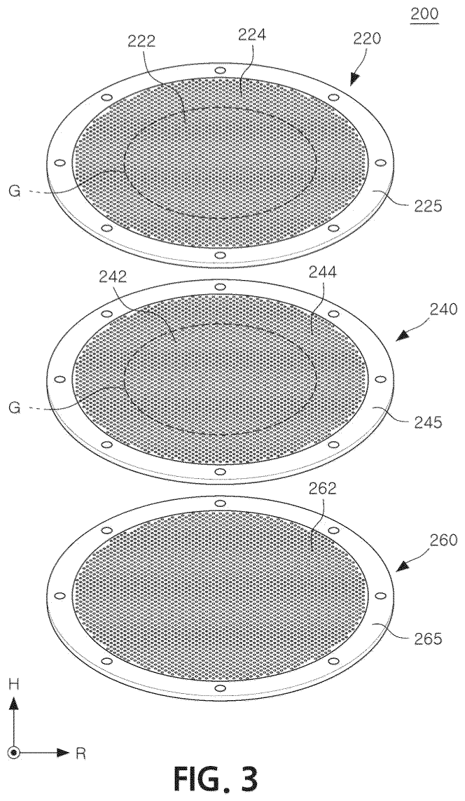

FIG. 1 is a cross-sectional view of a semiconductor wafer processing apparatus according to one or more embodiments. FIG. 2 is a diagram of a semiconductor wafer processing apparatus according to one or more embodiments. FIG. 3 is a perspective view of a plurality of grid electrodes according to one or more embodiments.

Referring to FIGS. 1 to 3, a semiconductor wafer processing apparatus 1 may include a plasma chamber 10, a processing chamber 20, and an ion extraction device 200 including a plurality of grid electrodes.

To facilitate the description of the semiconductor wafer processing apparatus 1, the directions illustrated in the drawings will first be defined. The direction from the plasma chamber 10 to the processing chamber 20 is defined as the height direction H of the semiconductor wafer processing apparatus 1, and the horizontal direction of the semiconductor wafer processing apparatus 1 is defined as the radial direction R.

The plasma chamber 10 may be filled with plasma gas from an external plasma gas supply source, and plasma P may be induced in the plasma chamber 10 by an inductively coupled plasma (ICP) antenna 600 provided on one side of the plasma chamber 10.

The inductively coupled plasma antenna 600 may heat electrons in the plasma chamber 10 to generate plasma P by forming a magnetic field that changes in time in a direction perpendicular to the plane formed by an antenna coil 620 as radio frequency (RF) power is supplied to an antenna coil 620.

The ion extraction device 200 may be disposed between the plasma chamber 10 and the processing chamber 20, and may extract ions from the plasma P generated in the plasma chamber 10, accelerate or focus the extracted ions, and provide an ion beam to the processing chamber 20.

A semiconductor process may be performed on a semiconductor wafer W in a processing chamber 20 using an ion beam discharged by the ion extraction device 200.

The processing chamber 20 may be connected to the plasma chamber 10 and the ion extraction device 200, and may provide a space in which the semiconductor wafer W is sealed from the outside. A semiconductor process may be performed on the wafer W in the sealed space of the processing chamber 20.

The semiconductor process may include, for example, at least one of a deposition process, an etching process, or a cleaning process. In this case, the etching process may include a high aspect ratio contacts (HARCs) etching process that is performed due to the demand for high integration of semiconductor substrates.

The processing chamber 20 may be formed of a metal material such as aluminum (Al), and in one or more embodiments, the processing chamber 20 may include a substrate passage through which a semiconductor wafer W is loaded or unloaded.

The processing chamber 20 may include an electrostatic chuck 22 that supports a semiconductor wafer W and a lower support 24 that supports the electrostatic chuck 22.

The electrostatic chuck 22 and the lower support 24 may be vertically raised or lowered by power supplied from the power supply unit 25.

The electrostatic chuck 22 may be a susceptor including a heating pattern 26, and the heating pattern 26 may heat the susceptor using power supplied from an external power supply device 25. The susceptor may be formed of a ceramic material such as aluminum nitride (AlN), aluminum oxide (Al₂O₃), etc.

The plasma P of the plasma chamber 10 may be extracted into ions by the ion extraction device 200 composed of a plurality of grid electrodes and accelerated or focused.

The plurality of grid electrodes may be provided in a plate shape and in which through-holes TH are formed, and may include a first grid electrode 220 and a second grid electrode 240.

At least one of the first grid electrode 220 and the second grid electrode 240 may be divided into a plurality of electrode plates in the radial direction R. That is, at least one of the first grid electrode 220 and the second grid electrode 240 may be separated into a plurality of electrode plates that are circular and that extend in the radial direction R

In detail, in one or more embodiments, the first grid electrode 220 may include a first electrode plate 222 and a second electrode plate 224, and the second grid electrode 240 may include a first electrode plate 242 and a second electrode plate 244.

The second electrode plate 224 of the first grid electrode 220 may be separated from the first electrode plate 222 by a gap G (e.g., a circular gap), and the second electrode plate 244 of the second grid electrode 240 may be separated from the first electrode plate 242 by a gap G (e.g., a circular gap). The second electrode plate 224 may surround the outer periphery of the first electrode plate 222, and the second electrode plate 244 may surround the outer periphery of the first electrode plate 242.

Although each of the grid electrodes are shown to have two electrode plates, embodiments are not limited thereto, and more than two electrode plates may be implemented, and in some embodiments, a single electrode plate without a gap or separation may be implemented.

In addition, the ion extraction device 200 may further include a third grid electrode 260. The third grid electrode 260 may formed as one electrode plate, but may be divided into (e.g., radially separated into by circular gaps) a plurality of plates for plasma ion formation control.

The first grid electrode 220, the second grid electrode 240, and the third grid electrode 260 may be disposed and stacked on the inner sides of respective bezels 225, 245 and 265 coupled to the processing chamber 20.

In addition, the semiconductor wafer processing apparatus 1 of may include a reflector 500 disposed between the lower portion of the plurality of grid electrodes 220, 240 and 260 in the height direction H and the semiconductor wafer W. That is, the reflector 500 may be disposed between the ion extraction device 200 and the wafer W in direction H, which may correspond to a direction from the plasma chamber 10 to the processing chamber 20. The reflector 500 may include a plurality of reflector plates 510 that may be inclined with respect to the plurality of grid electrodes as is described later.

The plasma P in the plasma chamber 10 may be extracted into ions I through a plurality of grid electrodes 220, 240 and 260 of the ion extraction device 200 and accelerated or focused to become an ion beam that may process a semiconductor wafer W.

A reflector 500 may be optionally installed, and the ion beam may be neutralized while passing through the reflector 500 to become a neutral beam N. When a semiconductor process is performed with the neutral beam N, plasma-induced damage caused by ions or problems with charging of the wafer W by ions may be resolved.

Hereinafter, the shape of the voltage line connected to the divided electrode plates of the grid electrode will be specifically described.

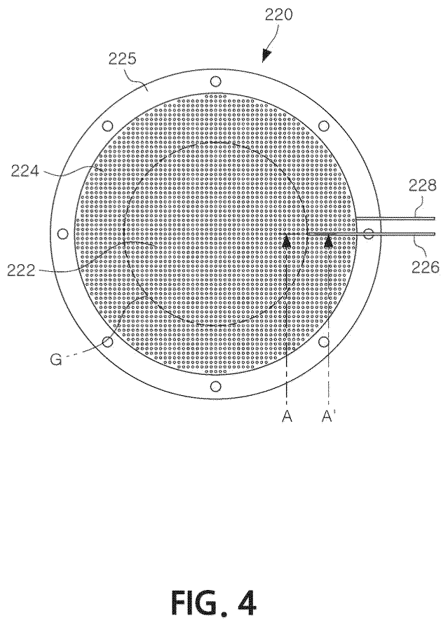

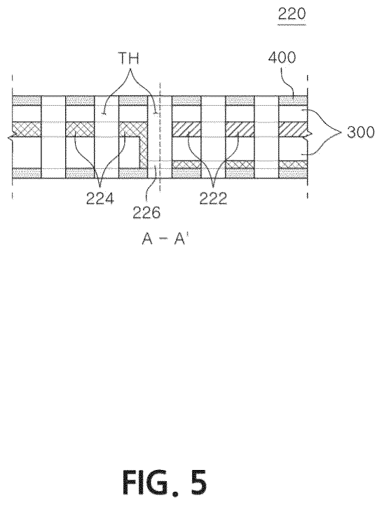

FIG. 4 is a plan view of a grid electrode according to one or more embodiments. FIG. 5 is a cross-sectional view partially enlarged along line A-A′ of FIG. 4 according to one or more embodiments.

Referring to FIGS. 4 and 5, the first grid electrode 220 may be provided in a plate shape in which through-holes TH are formed. The first grid electrode 220 may be divided into two electrode plates 222 and 224.

The two electrode plates may include a first electrode plate 222 and a second electrode plate 224 that are separated by a gap G, such that the second electrode plate 224 surrounds the outer edge of the first electrode plate 222.

In this case, the first electrode plate 222 may be defined as a center region electrode, and the second electrode plate 224 may be defined as an edge region electrode.

The first electrode plate 222 and the second electrode plate 224 of the first grid electrode 220 may be buried in an insulator 300, and voltages of different potential differences may be applied to the first electrode plate 222 and the second electrode plate 224.

The first voltage line 226 connected to the first electrode plate 222 may be bypassed with the second electrode plate 224 within the insulator 300, such that the first electrode plate 222 and the second electrode plate 224 may maintain an insulated state.

The second voltage line 228 connected to the second electrode plate 224 may be independently connected to the first voltage line 226 connected to the first electrode plate 222.

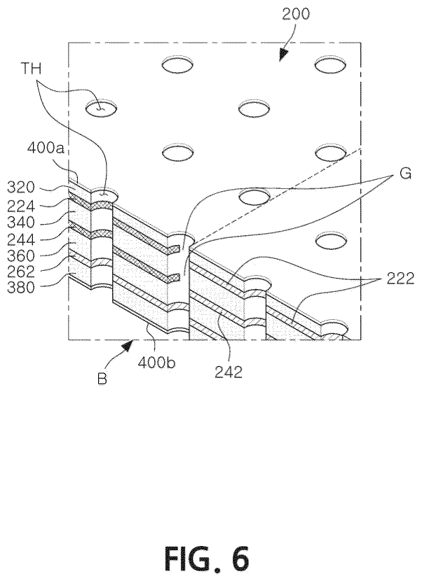

In addition, a coating layer 400 may be disposed on the upper and lower surfaces of the insulator 300. As shown in FIG. 6, the coating layer 400 may include an upper coating layer 400a and a lower coating layer 400b.

The coating layer 400 may be disposed for the purpose of minimizing the reaction of the gas that generates the plasma. The material and thickness of the coating layer 400 vary depending on the type of gas. For example, in the case of an ion beam/neutral beam facility using CF₄ gas, if the plasma using CF₄ gas directly contacts Al₂O₃, which is an insulator material, AlFx series particles may be generated, which may cause process defects. To suppress this reaction, the material of the upper surface coating layer 400 may be a carbon series coating that has low reactivity with CF₄ gas, or a Si, SiC, and SiO₂ coating that does not generate particles due to the reaction and may evaporate volatility. The carbon series coating may be deposited with a thickness in the range of about 1 to 10 μm using a Diamond Like Coating (DLC) coating method. Si, SiC, and SiO₂ may be coated with a chemical vapor deposition method and may be deposited with a thickness in the range of about 1 to 10 μm. If the thickness is 1 μm or less, there is a disadvantage that the lifespan of the component is shortened due to etching by reaction, and if the thickness is 10 μm or more, it takes a lot of time and cost depending on the deposition method, and thus, the thickness may be generally limited to 10 μm that may be applied.

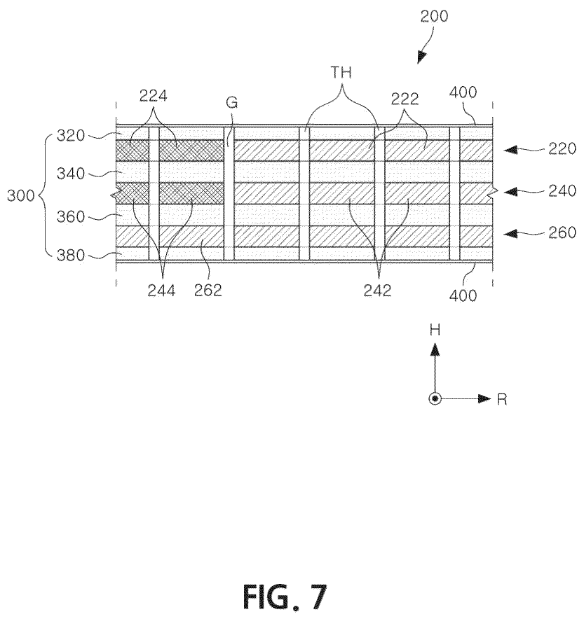

FIG. 6 is a cross-sectional perspective view illustrating a plurality of grid electrodes buried in an insulator according to one or more embodiments. FIG. 7 is a cross-sectional view as viewed in the direction of arrow B of FIG. 6 according to one or more embodiments.

Referring to FIGS. 6 and 7, the shape of an ion extraction device 200 composed of a plurality of grid electrodes is illustrated.

The ion extraction device 200 may include a first grid electrode 220, a second grid electrode 240, and a third grid electrode 260.

The first grid electrode 220, the second grid electrode 240, and the third grid electrode 260 may be disposed buried in the insulator 300.

The first grid electrode 220 may include a first electrode plate 222 and a second electrode plate 242 surrounding the outer periphery of the first electrode plate 222 and separated by a gap G, and the second grid electrode 240 may include a first electrode plate 242 and a second electrode plate 244 surrounding the outer periphery of the first electrode polite 242 and separated by a gap G.

For example, when a positive voltage (+) is applied to the first electrode plates 222 and 242, the first electrode plates 222 and 242 may extract ions. A negative voltage (−) may be applied to the second electrode plates 224 and 244, so that the second electrode plates 224 and 244 may accelerate and focus ions.

The third grid electrode 260 may include a third electrode plate 262 and may be grounded externally, so that the third electrode plate 262 may prevent the reverse movement of ions. The thickness of each of the first electrode plates 222 and 242, the second electrode plates 224 and 244, and the third electrode plate 262 may be in the range of 50 μm or more and 300 μm or less in the case of a ceramic buried electrode, but is not limited thereto.

If the thickness is less than 50 μm, reliability problems in the electrode quality, such as the electrode being short-circuited due to the porosity of the electrode layer, may occur, and thus, an electrode layer thickness of 50 to 300 μm may be selected. The electrode layer thickness exceeding 300 μm may not be easy to manufacture with electrode paste.

In addition, the gap G between the first electrode plates 222 and 242 and the second electrode plates 224 and 244 may have a width in a range of 0.5 mm to 4 mm, and the width of the gap G may be determined according to the dielectric strength for the potential difference between the first electrode plates 222 and 242 and the second electrode plates 224 and 244. In one or more embodiments, when Al₂O₃ 98% is selected as the material of the electrode, the dielectric strength is 9 kV/mm, and in this case, a minimum thickness of about 0.4 mm may be required to withstand insulation breakdown at 4 kV Considering the manufacturing tolerance, the gap G may have a thickness of 0.5 mm or more. If the gap G exceeds 4 mm, issues may occur in ion extraction and focusing.

The insulator 300 may include a plurality of insulating plates, and the plurality of insulating plates may include a first insulating plate 320, a second insulating plate 340, a third insulating plate 360, and a fourth insulating plate 380 sequentially arranged in the direction from the plasma chamber 10 to the processing chamber 20, for example, downward in the height direction H of the semiconductor wafer processing apparatus 1.

In this case, the first grid electrode 220 may be disposed between the first insulating plate 320 and the second insulating plate 340, the second grid electrode 240 may be disposed between the second insulating plate 340 and the third insulating plate 360, and the third grid electrode 260 may be disposed between the third insulating plate 360 and the fourth insulating plate 380.

The thicknesses of the first to fourth insulating plates 320, 340, 360 and 380 may be determined according to the dielectric strength for the potential difference between the first grid electrode 220 and the second grid electrode 240. In one or more embodiments, the operating range of the first grid electrode 220 may be at most 2 kV, the operating range of the second grid electrode 240 may be at the level of −2 kV, and the potential difference between the first grid electrode 220 and the second grid electrode 240 may be 4 kV. For example, if the material of the electrode is selected as Al₂O₃ 98%, the dielectric strength may be 9 kV/mm, and in this case, to withstand insulation breakdown at 4 kV, each insulating plate may require a minimum thickness of 0.4 mm, and considering the manufacturing tolerance, a thickness of 0.5 mm or more may be required. In terms of insulation breakdown, each insulating plate may be stable at the thickness of 0.5 mm or more, but in terms of beam focusing, the focusing area may be depending on the thickness of the insulating plate.

When the thickness of the insulating plate was within the range of 4 mm, the results may be stable, and when the thickness exceeded 4 mm, issues may occur in which the material and processing costs increased and the beam focusing area shifted.

In one or more embodiments, the thickness of the first insulating plate 320 to the fourth insulating plate 380 may range from 0.5 mm to 4 mm, but embodiments are limited thereto. The thickness of each insulating plate may be maintained the same, and the gap between respective electrode plates may be adjusted by varying the thickness of the insulating plate according to the ion extraction, acceleration, and focus setting of the plasma.

Thus, the arrangement according to one or more embodiments may be manufactured by pasting and sintering an electrode material on a dielectric green sheet.

A coating layer 400 may be provided. An upper coating layer 400a may be provided on the upper surface of the insulator 300, and a lower cover layer 400b may be provided on a lower surface of the insulator 300.

Through-holes TH may be formed in the insulator 300, the first grid electrode 220, the second grid electrode 240, the third grid electrode 260, and the coating layer 400 (e.g., layers 400a and 400b), and the through-holes TH may extend in the height direction H, so that the plasma chamber 10 and the processing chamber 20 are connected by the through-holes TH. The through-holes TH may become a path for plasma ions in the plasma chamber 10 to move to the processing chamber 20.

The third grid electrode 260 may be formed of one electrode plate 262, but may be divided into multiple plates for plasma ion formation control.

In this case, the material of the grid electrode may include at least one of molybdenum (Mo), stainless steel (SuS), and silicon (Silicon), and the material of the insulator 300 may include at least one of aluminum oxide (Al₂O₃), yttrium oxide (Y₂O₃), and polymer.

In addition, the material of the coating layer 400 may include at least one of silicon (Si), silicon carbide (SiC), and carbon (C).

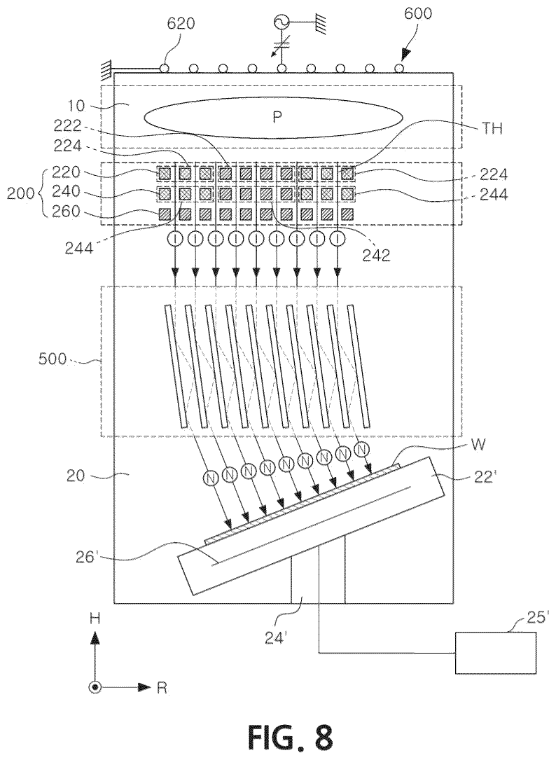

FIG. 8 is a diagram of a semiconductor wafer processing apparatus according to one or more embodiments.

The example embodiment of FIG. 8 is substantially the same as the example embodiment of FIG. 2 except for the shapes of the electrostatic chuck 22′ and the lower support 24′ in the processing chamber 20.

The lower support 24′ of FIG. 8 may be raised, tilted, and rotated, similar to the lower support 24 of FIG. 2. The electrostatic chuck 22′ may also heat the heating pattern 26′ using power supplied from an external power supply device 25′.

The electrostatic chuck 22′ of FIG. 8 may be inclined to correspond to the inclination of the reflector 500 so that the ion beam I passes through the reflector 500 and the neutralized neutral beam N uniformly reaches the semiconductor wafer W.

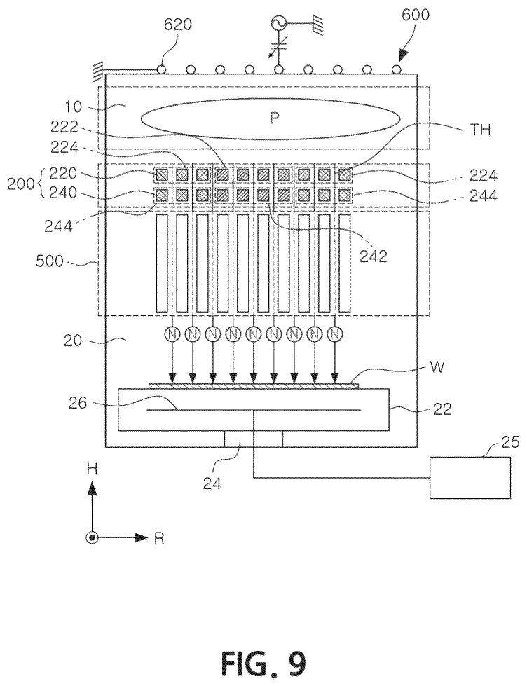

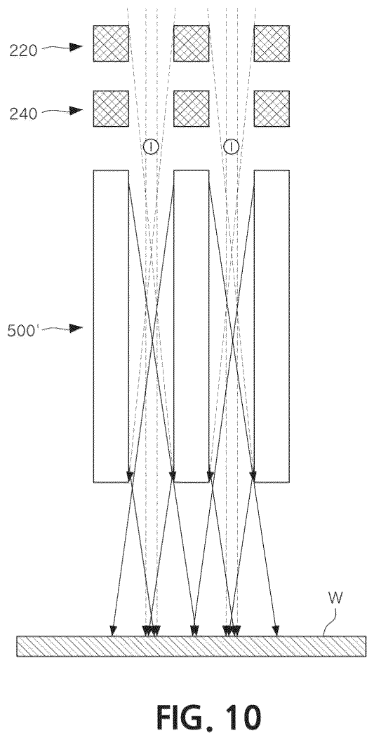

FIG. 9 is a diagram of a semiconductor wafer processing apparatus according to one or more embodiments. FIG. 10 is a diagram of an ion beam being neutralized into a neutral beam through a reflector used in a semiconductor wafer processing apparatus according to one or more embodiments.

The semiconductor wafer processing apparatus of FIG. 9 and FIG. 10 may include the first grid electrode 220 and the second grid electrode 240 that may be similar to those described above in relation to FIG. 2.

A reflector 500′ of FIG. 9 and FIG. 10 may be configured as a hole-type reflector by extending the third grid electrode 260 in the height direction H. The reflector 500′ may be configured as a hole-type reflector configured by overlapping multiple grid electrodes, such as a third grid electrode, a fourth grid electrode and the like.

In FIG. 9 and FIG. 10, plasma P in the plasma chamber 10 may be extracted into ions I through the first grid electrode 220 and the second grid electrode 240 of the ion extraction device 200 and accelerated or focused to become an ion beam capable of processing a semiconductor wafer W.

The ion beam extracted through the first grid electrode 220 and the second grid electrode 240 may pass through a hole-type reflector 500′ to be neutralized and becomes a neutral beam N. When a semiconductor process is performed with the neutral beam N, the problem of plasma-induced damage caused by ions or charging of the wafer W by ions may be solved.

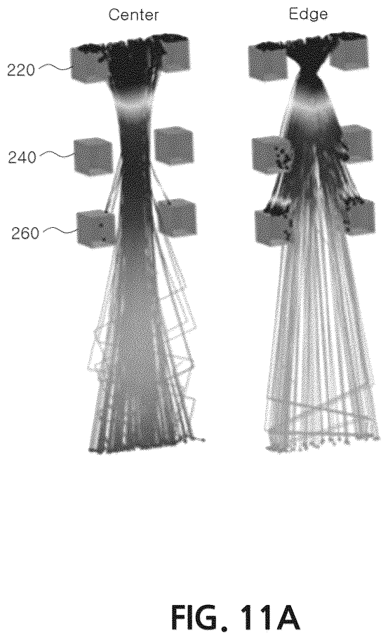

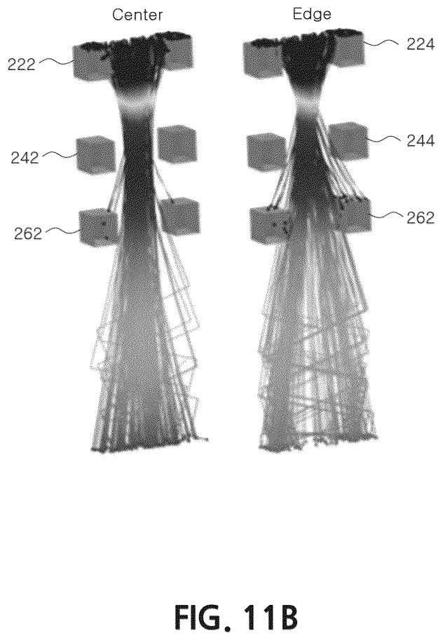

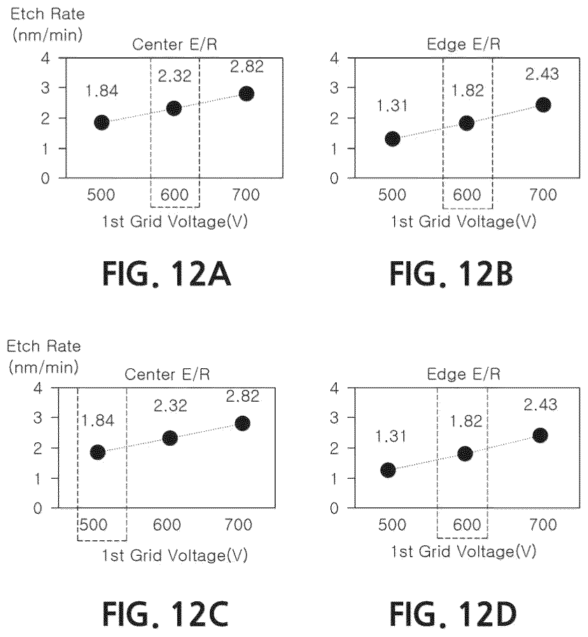

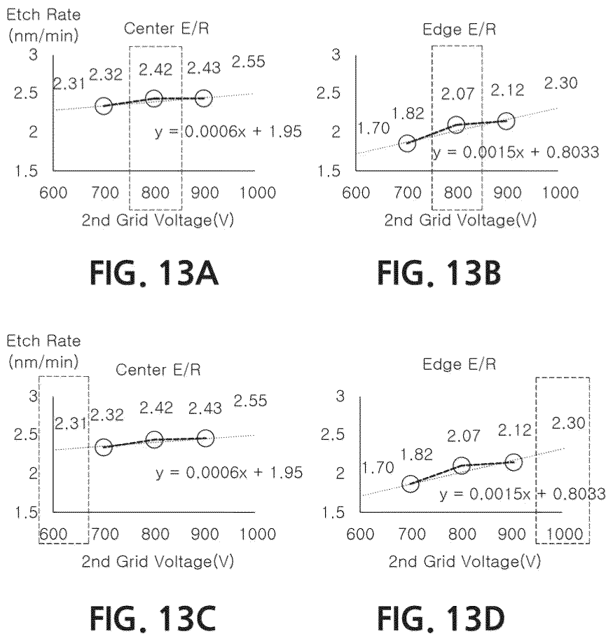

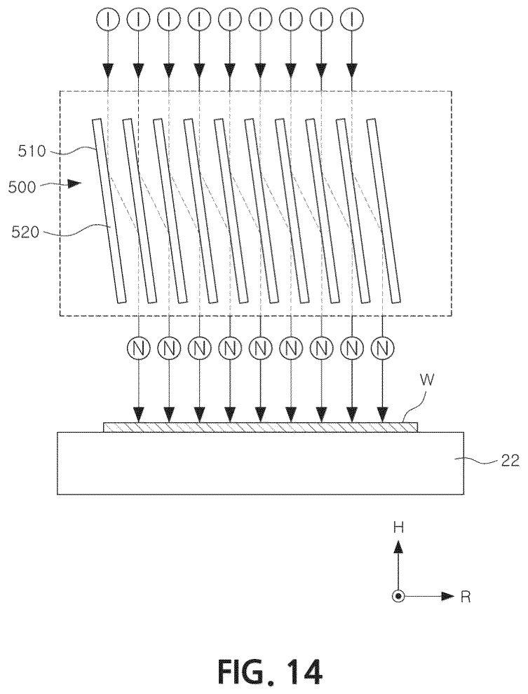

FIG. 11A is a diagram illustrating simulation of the ion discharge shape when a first grid electrode and a second grid electrode are not divided into a center region and an edge region according to one or more embodiments. FIG. 11B is a diagram illustrating simulation of the ion discharge shape when the first grid electrode and the second grid electrode are divided into a center region and an edge region according to one or more embodiments. FIGS. 12A and 12B are graphs illustrating experimental results of etching rates according to one or more embodiments. FIGS. 12C and 12D are graphs illustrating experimental results of etching rates according to one or more embodiments. FIGS. 13A and 13B are graphs illustrating experimental results of an etching rate according to one or more embodiments. FIGS. 13C and 13D are graphs illustrating experimental results of an etching rate according to one or more embodiments.

Specifically, FIGS. 12A and 12B are graphs of the experimental results of the etching rate that proceeds in the center region and the edge region of a semiconductor wafer when the same voltage is applied to the first grid electrode when the first grid electrode and the second grid electrode are not divided into a center region and an edge region, and FIGS. 12C and 12D are graphs of the experimental results of the etching rate that proceeds in the center region and the edge region of a semiconductor wafer when different voltages are applied to the first electrode plate and the second electrode plate of the first grid electrode when the first grid electrode and the second grid electrode are divided into a center region and an edge region.

FIGS. 13A and 13B are graphs of experimental results of an etching rate that occurs in the center region and edge region of a semiconductor wafer when the same voltage is applied to the first grid electrode when the first grid electrode and the second grid electrode are not divided into the center region and edge region, and FIGS. 13C and 13D are graphs of an experimental result of an etching rate that occurs in the center region and edge region of a semiconductor wafer when different voltages are applied to the first electrode plate and the second electrode plate of the first grid electrode when the first grid electrode and the second grid electrode are divided into the center region and edge region.

Referring to FIGS. 11A to 13D, the difference in etching rate will be described by comparing the case where the first grid electrode 220 and the second grid electrode 240 are not divided into the electrode plates of the center region and the edge region and the case where they are separated.

FIG. 11A is a simulation image of an ion beam that reaches a semiconductor wafer W when the plasma of the plasma chamber 10 is extracted as ions and accelerated or focused when the first grid electrode 220 and the second grid electrode 240 are not divided into a center region and an edge region, respectively.

Referring to FIG. 11A, the loss of the ion beam flux reaching the semiconductor wafer W is greater in the edge region than in the center region.

Since the loss of the ion beam flux is greater in the edge region, an imbalance occurs in which the etching rate is greater in the center region and less in the edge region.

Referring to FIGS. 12A and 12B, when the first grid electrode 220 and the second grid electrode 240 are not divided into the center region and the edge region, the experimental results of the etching rate that occurs in the center region and the edge region of the semiconductor wafer W when the same voltage is applied to the first grid electrode 220 are shown.

For example, when a voltage of 600 V is uniformly applied to the entire center region and edge region of the first grid electrode 220, the etching rate of the center region of the semiconductor wafer W is 2.32 nm/min, and the etching rate of the edge region is 1.82 nm/min. In this case, the difference between the etching rate of the center region and the etching rate of the edge region is 0.5 nm/min.

In addition, referring to FIGS. 13A and 13B, when the first grid electrode 220 and the second grid electrode 240 are not divided into a center region and an edge region, the experimental results of the etching rate that occurs in the center region and the edge region of the semiconductor wafer W when the same voltage is applied to the second grid electrode 240 are shown.

For example, when a voltage of 800 V is uniformly applied to the entire center region and edge region of the second grid electrode 240, the etching rate of the center region of the semiconductor wafer W is 2.42 nm/min, and the etching rate of the edge region is 2.07 nm/min. In this case, the difference between the etching rates of the center region and the edge region is 0.35 nm/min. When the same voltage is applied to a single grid electrode plate as above, a difference occurs in the etching rates that occur in the center region and the edge region of the semiconductor wafer W.

FIG. 11B is a simulation image of an ion beam in which plasma in a plasma chamber 10 is extracted as ions to be accelerated or focused and to reach a semiconductor wafer W when the first grid electrode 220 and the second grid electrode 240 are divided into center region electrodes 222 and 242 and edge region electrodes 224 and 244, respectively, and voltages with different potential differences are applied to the center region electrodes and the edge region electrodes.

By applying a higher voltage to the edge region electrodes 224 and 244 than to the center region electrodes 222 and 242, the ion beam fluxes reaching the center region and edge region of the semiconductor wafer W are almost similar.

Referring to FIGS. 12C and 12D, when the first grid electrode 220 and the second grid electrode 240 are divided into the center region electrodes (222 and 242, first electrode plates) and the edge region electrodes (224 and 244, second electrode plates), respectively, and when different voltages are applied to the first electrode plate 222 and the second electrode plate 224 of the first grid electrode 220, the experimental results of the etching rate that occurs in the center region (Center) and the edge region (Edge) of the semiconductor wafer W are shown.

For example, when a voltage of 500 V is applied to the center region electrode 222 of the first grid electrode 220 and a voltage of 600 V is applied to the edge region electrode 224, the etching rate of the center region of the semiconductor wafer W is 1.84 nm/min, and the etching rate of the edge region is 1.82 nm/min. In this case, the difference between the etching rate of the center region and the etching rate of the edge region is 0.02 nm/min.

In addition, referring to FIGS. 13C and 13D, when the first grid electrode 220 and the second grid electrode 240 are divided into center region electrodes (222 and 242, first electrode plates) and edge region electrodes (224 and 244, second electrode plates), respectively, and when different voltages are applied to the first electrode plate 242 and the second electrode plate 244 of the second grid electrode 240, the experimental results of the etching rate that occurs in the center region (Center) and the edge region (Edge) of the semiconductor wafer W are shown.

For example, when a voltage of 600 V is applied to the center region electrode 242 of the second grid electrode 240 and a voltage of 1000 V is applied to the edge region electrode 224, the etching rate of the center region of the semiconductor wafer W is 2.31 nm/min, and the etching rate of the edge region is 2.30 nm/min. In this case, the difference between the etching rate of the center region and the etching rate of the edge region is 0.01 nm/min.

As described above, when the first grid electrode 220 and the second grid electrode 240 are divided into first electrode plates 222 and 242 and second electrode plates 224 and 244, respectively, and different voltages are applied to the first electrode plates 222 and 242 and the second electrode plates 224 and 244, the etching rates in the center region and the edge region may be controlled very precisely so that there is almost no difference.

By controlling the voltage in the edge region to be greater than the voltage in the center region, the loss of ion beam flux in the edge region may be prevented, so that the etching rates in the center region and the edge region may be controlled to be almost similar.

As described in FIG. 11B, by adopting a structure in which the electrode plates of the first grid electrode or the second grid electrode are separated and applying different voltages, the distribution of plasma reaching the semiconductor wafer may be made uniform. When the distribution of plasma reaching the semiconductor wafer becomes uniform, the difference in etching rate between the center and the edge of the semiconductor wafer also becomes uniform.

In addition, since the voltage applied to the electrode plate of the first grid electrode or the second grid electrode to the separated structure may be independently controlled, the etching of the semiconductor wafer may be precisely controlled.

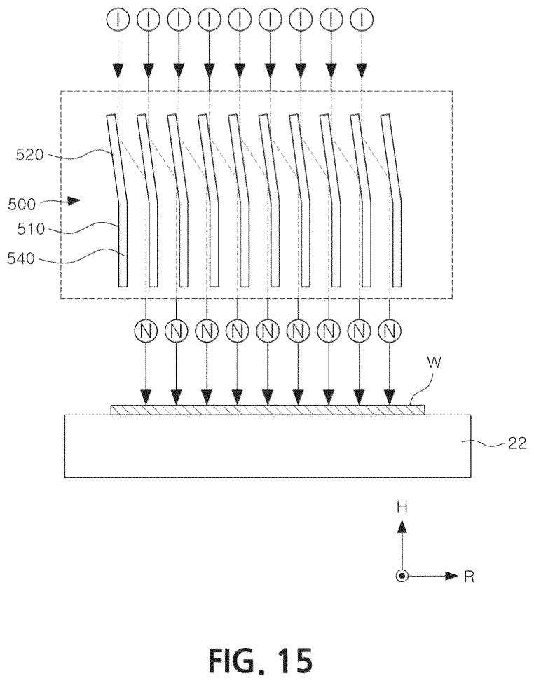

FIG. 14 is a diagram of an ion beam being neutralized by a reflector according to one or more embodiments. FIG. 15 is a diagram of an ion beam being neutralized by a reflector according to one or more embodiments.

As shown in FIGS. 14 and 15, the reflector 500 may include a plurality of reflector plates 510 that are aligned with the through-holes TH of the plurality of grid electrodes.

The reflector 500 of FIG. 14 may have a plurality of reflector plates 510 that are inclined portions 520 of the same slope disposed continuously in the radial direction R. That is, the reflector plates 510 may be inclined with the same slope with respect to the plurality of grid electrodes.

The plasma of the plasma chamber 10 may be extracted as ions I through the ion extraction device 200, accelerated or focused, and introduced into the processing chamber 20 in the form of an ion beam.

Although semiconductor processing of a semiconductor wafer is possible with an ion beam, the ions may be neutralized by passing through a reflector 500 to resolve the problem of plasma-induced damage caused by ions or charging of the wafer by ions.

The reflector 500 of FIG. 15 may include a plurality of reflector plates 510. Each reflector plate 510 may include an inclined portion 520 adjacent to a plurality of grid electrodes 220, 240 and 260, and a vertical portion 540 extending from the inclined portion 520 and adjacent to the semiconductor wafer W. That is, the inclined portions 520 may be closer to the grid electrodes than the vertical portions 540, and the inclined portions 520 may have the same slope and inclination with respect to the grid electrodes.

The plasma of the plasma chamber 10 may be extracted as ions I through the ion extraction device 200, accelerated or focused, and introduced into the processing chamber 20 in the form of an ion beam.

Although semiconductor processing of a semiconductor wafer is possible with an ion beam, the ions may be neutralized by passing through the reflector 500 to resolve the problem of plasma-induced damage caused by ions or charging of the wafer by ions.

By employing a reflector 500 as illustrated in FIG. 14 and FIG. 15, the ion beam may be neutralized into a neutral beam so that the ion beam does not reach the semiconductor wafer but the neutral beam reaches the semiconductor wafer, thereby resolving the problem of plasma-induced damage caused by ions or charging of the wafer by ions.

As set forth above, in a semiconductor wafer processing apparatus according to one or more embodiments, a plasma distribution reaching a semiconductor wafer may be uniform by dividing a grid electrode and applying different electrodes thereto.

In addition, by dividing a grid electrode and enabling the plasma distribution to be uniform, the etching rate between a center and an edge of the semiconductor wafer may be uniform.

In addition, by generating plasma with an inductively coupled plasma antenna capable of controlling the distribution, dispersing a uniform ion beam to a center region and an edge region of a wafer with the divided grid electrode, and using a reflector neutralizing ion beam, the neutral beam reaching the semiconductor wafer may be uniformly controlled.

In addition, by using a reflector to allow the center beam to reach a semiconductor wafer, the problem of plasma-induced damage caused by ions or wafer charging caused by ions may be resolved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor wafer processing apparatus, comprising:
a plasma chamber;
a processing chamber connected to the plasma chamber and comprising an electrostatic chuck configured to support a semiconductor wafer;
a plurality of grid electrodes between the plasma chamber and the processing chamber; and
through-holes extending through the plurality of grid electrodes,
wherein the plurality of grid electrodes comprise a first grid electrode and a second grid electrode spaced apart from the first grid electrode in a direction from the plasma chamber to the processing chamber, and
wherein at least one of the first grid electrode and the second grid electrode comprises a plurality of electrode plates.

2. The semiconductor wafer processing apparatus of claim 1, wherein at least one of the first grid electrode and the second grid electrode is buried in an insulator, and
wherein voltages having different potential differences are respectively applied to the plurality of electrode plates.

3. The semiconductor wafer processing apparatus of claim 2, wherein each electrode plate of the plurality of electrode plates comprises a first electrode plate and a second electrode plate surrounding an outer periphery of the first electrode plate,
wherein a gap is between the first electrode plate and the second electrode plate, and
wherein a first voltage line connected to the first electrode plate and a second voltage line connected to the second electrode plate are buried in the insulator.

4. The semiconductor wafer processing apparatus of claim 2, wherein the insulator comprises a plurality of insulating plates,
wherein the plurality of insulating plates comprise a first insulating plate, a second insulating plate, a third insulating plate, and a fourth insulating plate sequentially arranged in the direction from the plasma chamber to the processing chamber,
wherein the plurality of grid electrodes further comprise a third grid electrode,
wherein the first grid electrode is between the first insulating plate and the second insulating plate,
wherein the second grid electrode is between the second insulating plate and the third insulating plate, and
wherein the third grid electrode is between the third insulating plate and the fourth insulating plate.

5. The semiconductor wafer processing apparatus of claim 2, wherein at least one of the first grid electrode and the second grid electrode has a thickness in a range of 50 μm to 300 μm,
wherein the insulator has a thickness in a range of 0.5 mm to 4 mm,
wherein a material of the first grid electrode and a material of the second grid electrode comprise at least one of molybdenum (Mo), stainless steel (SuS), and silicon, and
wherein a material of the insulator comprises at least one of aluminum oxide (Al₂O₃), yttrium oxide (Y₂O₃), and polymer.

6. The semiconductor wafer processing apparatus of claim 2, further comprising a coating layer,
wherein the coating layer comprises an upper coating layer on an upper surface of the insulator and a lower coating layer on a lower surface of the insulator,
wherein each of the upper coating layer and the lower coating layer has a thickness in a range of 1 μm to 10 μm, and
wherein a material of the coating layer comprises at least one of silicon (Si), silicon carbide (SiC), and carbon (C).

7. The semiconductor wafer processing apparatus of claim 1, wherein a first voltage is applied to the first grid electrode and a second voltage is applied to the second grid electrode,
wherein the first voltage is different from the second voltage, and
wherein a potential difference between the first grid electrode and the second grid electrode is 4 kV or less.

8. The semiconductor wafer processing apparatus of claim 1, further comprising a reflector below the plurality of grid electrodes and above the semiconductor wafer in the direction from the plasma chamber to the processing chamber.

9. The semiconductor wafer processing apparatus of claim 8, wherein the reflector is below the second electrode grid, and
wherein the reflector is configured as a hole-type reflector that comprises a third grid electrode comprising holes corresponding to through-holes of the first grid electrode and the second grid electrode.

10. The semiconductor wafer processing apparatus of claim 8, wherein the reflector comprises a plurality of reflector plates, and
wherein:
each of the plurality of reflector plates is continuously inclined with respect to the plurality of grid electrodes, or
each of the plurality of reflector plates comprise an inclined portion and a vertical portion extending from the inclined portion.

11. The semiconductor wafer processing apparatus of claim 1, wherein the plurality of electrode plates are separated by a circular gap,
wherein the circular gap is in a range of 0.5 mm to 4 mm.

12. A semiconductor wafer processing apparatus comprising:
a plasma chamber in which ions are generated;
a processing chamber configured to process a semiconductor wafer using ions generated in the plasma chamber;
an ion extraction device configured to extract and accelerate ions in the plasma chamber and comprising a plurality of grid electrodes; and
through-holes extending through the plurality of grid electrodes,
wherein the plurality of grid electrodes comprise a first grid electrode and a second grid electrode spaced apart from the first grid electrode in a direction from the plasma chamber to the processing chamber,
wherein at least one of the first grid electrode and the second grid electrode comprises a plurality of electrode plates, and
wherein voltages having different potential differences are applied to the plurality of electrode plates, respectively.

13. The semiconductor wafer processing apparatus of claim 12, wherein the plurality of grid electrodes are buried in an insulator,
wherein the insulator comprises a plurality of insulating plates,
wherein the plurality of insulating plates comprise a first insulating plate, a second insulating plate, a third insulating plate, and a fourth insulating plate sequentially arranged in the direction from the plasma chamber to the processing chamber,
wherein the plurality of grid electrodes further comprise a third grid electrode,
wherein the first grid electrode is between the first insulating plate and the second insulating plate,
wherein the second grid electrode is between the second insulating plate and the third insulating plate, and
wherein the third grid electrode is between the third insulating plate and the fourth insulating plate.

14. The semiconductor wafer processing apparatus of claim 13, wherein at least one of the first grid electrode and the second grid electrode comprise a center region electrode and an edge region electrode, and
wherein a first voltage line connected to the center region electrode and a second voltage line connected to the edge region electrode are buried within the insulator.

15. The semiconductor wafer processing apparatus of claim 13, wherein at least one of the first grid electrode and the second grid electrode has a thickness in a range of 50 μm to 300 μm,
wherein the insulator has a thickness in a range of 0.5 mm to 4 mm,
wherein a material of the first grid electrode and a material of the second grid electrode comprise at least one of molybdenum (Mo), stainless steel (SuS), and silicon, and
wherein a material of the insulator comprises at least one of aluminum oxide (Al₂O₃), yttrium oxide (Y₂O₃), and polymer.

16. The semiconductor wafer processing apparatus of claim 13, further comprising a coating layer,
wherein the coating layer comprises an upper coating layer on an upper surface of the insulator and a lower coating layer on a lower surface of the insulator,
wherein each of the upper coating layer and the lower coating layer has a thickness in a range of 1 μm to 10 μm, and
wherein a material of the coating layer comprises at least one of silicon (Si), silicon carbide (SiC), and carbon (C).

17. The semiconductor wafer processing apparatus of claim 12, wherein a first voltage is applied to the first grid electrode and a second voltage is applied to the second grid electrode,
wherein the first voltage is different from the second voltage, and
wherein a potential difference between the first grid electrode and the second grid electrode is 4 kV or less.

18. The semiconductor wafer processing apparatus of claim 12, further comprising:
an inductively coupled plasma antenna on one side of the plasma chamber;
an electrostatic chuck in a lower portion of the processing chamber and supporting the semiconductor wafer; and
a reflector between the ion extraction device and the semiconductor wafer, and configured to neutralize an ion beam extracted from the ion extraction device,
wherein the reflector comprises a plurality of reflector plates that are continuously inclined with respect to the plurality of grid electrodes.

19. The semiconductor wafer processing apparatus of claim 18, wherein the reflector is below the second electrode grid, and
wherein the reflector is configured as a hole-type reflector that comprises a third grid electrode comprising holes corresponding to through-holes of the first grid electrode and the second grid electrode.

20. A semiconductor wafer processing apparatus comprising:
a plasma chamber;
an inductively coupled plasma antenna on an upper side of the plasma chamber;
a processing chamber connected to and communicating with the plasma chamber, the processing chamber comprising an electrostatic chuck configured to support a semiconductor wafer;
an ion extraction device between the plasma chamber and the processing chamber, the ion extraction device comprising an insulator and a plurality of grid electrodes;
through-holes extending through the plurality of grid electrodes; and
a reflector between the ion extraction device and the semiconductor wafer, and configured to neutralize an ion beam extracted from the ion extraction device, the reflector comprising a plurality of reflector plates that are continuously inclined with respect to the plurality of grid electrodes,
wherein the plurality of grid electrodes comprise a first grid electrode, a second grid electrode and a third grid electrode sequentially arranged in a direction from the plasma chamber to the processing chamber,
wherein the insulator comprises a first insulating plate between the first grid electrode and a second insulating plate between the second grid electrode and the third grid electrode, and
wherein at least one of the first grid electrode, the second grid electrode, and the third grid electrode comprises a plurality of electrode plates, and voltages having different potential differences are respectively applied to the plurality of electrode plates.
